(19) United States
(12) Patent Application Publication
(10) Pub. No.: US 2007/0160759 A1
(43) Pub. Date: Jul. 12, 2007

(54) Method for coating surfaces exposed to hydrocarbon fluids

(75) Inventors: David Forrest Dye, Cincinnati, OH (US); John Ackerman, Laramie, WY (US); Bhupendra K. Gupta, Cincinnati, OH (US)

Correspondence Address: JOHN S. BEULICK (12729);C/O ARMSTRONG TEASDALE LLP, ONE METROPOLITAN SQUARE, SUITE 2600, ST. LOUIS, MO, 63102-2740, US

(73) Assignee: General Electric Company

(21) Appl. No.: 11/328,858

(22) Filed: Jan. 10, 2006

(51) Int. Cl. C23C 16/00

(52) U.S. Cl. 427/252

(57) ABSTRACT

A method for at least partially coating a surface of an object with a layer of platinum. The method includes applying a platinum precursor material to the object surface, evaporating the platinum precursor material from the object surface such that a residue comprising platinum remains on the surface, and heating the object such that the residue evaporates and re-deposits on the object surface as a layer comprising platinum.

### BACKGROUND OF THE INVENTION

The present invention relates generally to coatings that facilitate inhibiting the formation and/or adhesion of deposits on surfaces that contact hydrocarbon fluids, and more specifically to methods and apparatus for coating a surface that contacts a hydrocarbon fuel to facilitate reducing deposition of carbonaceous deposits thereon.

Thermal instability, or in the case of fuels, fuel instability, generally refers to the formation of undesired deposits that occur when hydrocarbon fluids, for example fuels and lubricating oils, are at elevated temperatures, for example generally above about 105° C. In the case of fuels, there may be two distinct mechanisms occurring within two overlapping temperature ranges. In the first mechanism, sometimes referred to as “coking”, an increase in a formation rate of coke deposits may occur above temperatures of about 345° C. Coke formation can be caused by hydrocarbon pyrolysis, and may sometimes limit usefulness of the fuel. A second mechanism may occur at lower temperatures, generally in the range of about 105° C. to about 345° C., and can involve oxidation reactions that may lead to polymerization and/or carbonaceous gum deposits.

A layer of platinum, sometimes referred to as a platinum coke barrier coating (CBC), has been used on surfaces that are exposed to hydrocarbon fluids to facilitate reducing deposition of carbonaceous deposits. For example, see U.S. Pat. No. 6,808,816 (Mancini et al.). At least some known methods of depositing a layer of platinum may include coating a surface by evaporating platinum precursor materials, for example platinum acetyl acetone or platinum pentanedionate, and exposing the surface to the resulting vapors. However, such known deposition methods may be less efficient than desired, for example yielding only about 10% platinum from the precursor material. Moreover, such known deposition methods may utilize equipment, for example, a chemical vapor deposition (CVD) reactor, that evaporates the precursor materials and channels the resulting vapors into a chamber containing a part to be coated. The cost of acquiring, leasing, operating, and/or maintaining such equipment may increase a cost of depositing a platinum layer and therefore fabricating coated parts. Moreover, loading parts into and unloading coated parts from such equipment may increase a time of fabricating coated parts. Furthermore, such equipment may generally coat all exposed surfaces of a part. Accordingly, covering surfaces that are not desired to be coated may increase a time and/or cost of fabricating coated parts. Moreover, using such equipment may sometimes only be cost-effective if a batch of a plurality of parts are coated simultaneously.

### BRIEF DESCRIPTION OF THE INVENTION

In one aspect, a method is provided for at least partially coating a surface of an object with a layer of platinum. The method includes applying a platinum precursor material to the object surface, evaporating the platinum precursor material from the object surface such that a residue comprising platinum remains on the surface, and heating the object such that the residue evaporates and re-deposits on the object surface as a layer comprising platinum.

In another aspect, a method is provided for at least partially coating an object with a layer of platinum. The method includes applying a mixture of a platinum precursor material and a solvent to a surface of the object that will be exposed to a hydrocarbon fuel, evaporating the mixture of solvent and platinum precursor material from the object surface such that a residue comprising platinum remains on the surface, covering at least a portion of the object surface with a covering, and heating the object such that the residue evaporates and re-deposits on the object surface as a layer comprising platinum.

### BRIEF DESCRIPTION OF THE DRAWINGS

FIG. 1 is a cross-sectional view of an exemplary object coated with an exemplary embodiment of a coating system.

FIG. 2 is a flowchart illustrating an exemplary embodiment of a method of coating the object shown in FIG. 1 with the coating system shown in FIG. 1.

### DETAILED DESCRIPTION OF THE INVENTION

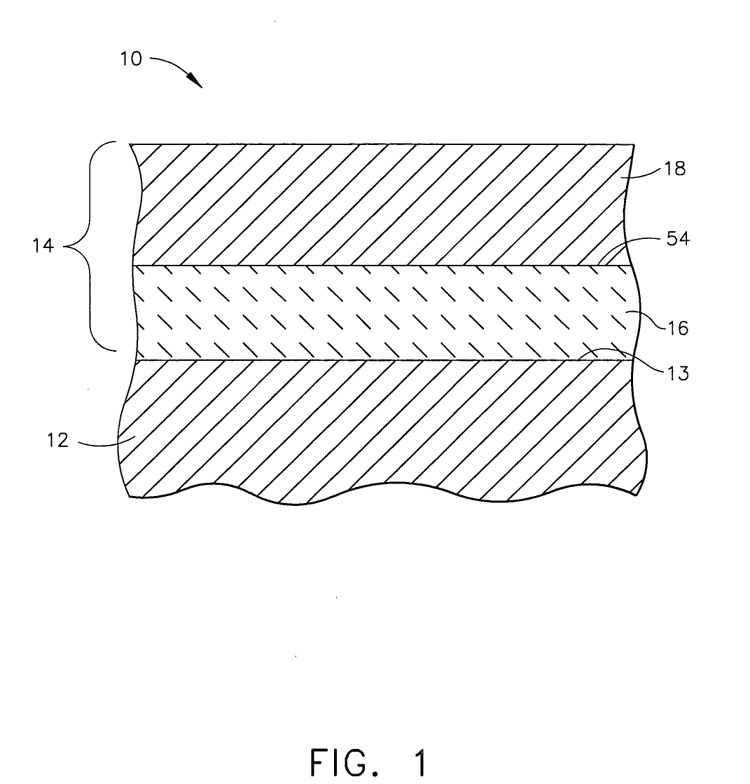

FIG. 1 is a cross-sectional view of an exemplary object 10 having a wall 12 with a surface 13 coated with an exemplary embodiment of a coating system 14. In the exemplary embodiment, wall 12 contacts a hydrocarbon fluid, such as, but not limited to, a fuel and/or oil, at elevated temperatures, for example generally above about 105° C. Coating system 14 may facilitate preventing or reducing the formation and/or adhesion of carbonaceous deposits that would otherwise adhere to wall surface 13 if maintained at a temperature of generally above about 105° C. Coating system 14 may be used with any hydrocarbon fluid in which carbonaceous gum (or other polymers) deposits form when the fluid is subjected to elevated temperatures, for example generally above about 105° C. and sometimes more particularly at temperatures of about 105° C. to about 345° C., whether such fluid is pure hydrocarbon or a mixture of one or more hydrocarbons and one or more other substances. Although object 10 may be any object, in some embodiments object 10 is an object adapted to contain and/or transport hydrocarbon fluid at elevated temperatures, such as, but not limited to fuel nozzles, pipes, oil sumps, and/or heat exchangers of gas turbine engines. In some embodiments, object wall 12 transfers heat from an external heat source (not shown) to a hydrocarbon fluid.

In the exemplary embodiment, a liquid hydrocarbon fluid (not shown) contacts and flows across wall surface 13 protected by coating system 14, such that heat transferred to the fluid from an external heat source must be conducted through the coating system 14. Accordingly, coating system 14 may facilitate protecting object wall 12, and more specifically may facilitate reducing or preventing the formation and/or adhesion of carbonaceous deposits from the hydrocarbon fluid that may be caused by elevated temperatures of object wall 12 and the hydrocarbon fluid. Object wall 12 may be fabricated from any suitable material such that wall 12 is capable of performing the functions described herein, such as, but not limited to, steel and/or corrosion-resistant alloys of nickel and/or chromium. In some known situations, alloys containing iron, chromium and/or nickel may facilitate the formation of fuel thermal decomposition products such as, but not limited to, gum and coke in the fluid hydrocarbon fluid.

Coating system 14 includes a layer 18 of platinum on object wall surface 13 and, in some embodiments, a diffusion barrier layer 16 on surface 13 that separates platinum layer 18 from object wall surface 13. Although only one diffusion barrier layer 16 is illustrated, system 14 may include any number of diffusion barrier layers 16. Although only one platinum layer 18 is illustrated, system 14 may include any number of platinum layers 18. Moreover, in some embodiments system 14 may not include a diffusion barrier layer 16, such that platinum layer 18 is directly coated on object wall surface 13. In the exemplary embodiment, coating system 14 is generally continuous and completely covers all of object wall surface 13 that would otherwise contact the hydrocarbon fluid.

In the exemplary embodiment, platinum layer 18 may be generally reactive with the hydrocarbon fluid at elevated temperatures and may exhibit low emissivity toward the hydrocarbon fluid. For example, although platinum layer 18 may have other incident radiant energies, in some embodiments platinum layer 18 has an incident radiant energy of between about 500 and about 4,500 btu per square foot hour within a wavelength band of between about 2 and about 9 micrometers. Moreover, and for example, although platinum layer 18 may exhibit other reflectivities and emissivities, in some embodiments platinum layer 18 exhibits a reflectivity of between about 60% and about 100% and an emissivity of about 0.2 or less within a wavelength band of between about 2 and about 6 micrometers. Accordingly, platinum layer 18 may facilitate reducing radiation heat transfer to the hydrocarbon fluid from object wall 12. As such, the temperature of the hydrocarbon fluid, and therefore the tendency for the fluid to form carbonaceous deposits, may be reduced. Although platinum layer 18 may generally facilitate deposition of carbonaceous deposits at other rates, in some embodiment, and for example, platinum layer 18 may facilitate deposition at a rate of between about 0 and about 10 mg/cm³ cm. For example, in some embodiments platinum layer 18 may facilitate deposition of less than about 5 mg/cm³ cm. In some embodiments, and for example, although platinum layer 18 may have other surface roughnesses, to facilitate reducing emissivity, in some embodiments platinum layer 18 includes a surface roughness of about 1.0 micrometer or less. A surface roughness of about 1.0 micrometers or less may facilitate reducing a surface reaction time and/or concentration of deposit precursors (radicals and atoms) that may facilitate polymer growth.

In some embodiments, coating system 14, and more specifically platinum layer 18, may facilitate catalyzing the hydrocarbon fluid that eventually becomes sufficiently hot to form carbonaceous gum deposits to facilitate rapid formation of gum substances. As such, it is believed that platinum layer 18 may facilitate catalyzing the formation of carbonaceous gum substances in a hydrocarbon fluid to the extent that, in a flowing fluid system, the gum substances grow too quickly to allow them to adhere to object wall 12. Rather, gum substances may be found in the form of very fine particulate within the fluid.

Platinum layer 18 may include any suitable thickness capable of performing the functions described herein, which may depend, for example, on a surface roughness of object wall surface 13. Although platinum layer 18 may include other thicknesses, in some embodiments, and for example, platinum layer 18 includes a thickness of between about 50 and about 500 nanometers. For example, in some embodiments platinum layer 18 includes a thickness of between about 200 and about 350 nanometers. In the exemplary embodiment, platinum layer 18 is generally continuous and completely covers all of object wall surface 13 that would otherwise contact the hydrocarbon fluid.

Diffusion barrier layer 16 may facilitate preventing or reducing interdiffusion between platinum layer 18 and object wall 12, which in some situations may occur at elevated temperatures, for example above about 105° C. Diffusion barrier layer 16 may also facilitate protecting object wall 12 from chemical attack from contaminants in the hydrocarbon fluid, such as, but not limited to, sulfur and/or water that would form sulfuric acid and possibly pit object wall surface 13. Accordingly, diffusion barrier layer 16 may facilitate preventing or inhibiting reactions between constituents of the hydrocarbon fluid and object wall 12. Diffusion barrier layer 16 may include any suitable material such that layer 16 is capable of performing the functions described herein. For example, and although diffusion barrier layer 16 may include other materials, in some embodiments layer 16 includes ceramics such as, but not limited to, silica, alumina, yttria, hafnia, tantala, mullite, and/or complex chemical combinations of silica with boron, phosphorous, and/or alumina. Diffusion barrier layer 16 may include any suitable thickness capable of performing the functions described herein. Although diffusion barrier layer 16 may include other thicknesses, in some embodiments, and for example, diffusion barrier layer 16 includes a thickness of between about 500 and about 1500 nanometers. For example, in some embodiments diffusion barrier layer 16 includes a thickness of between about 700 and about 1300 nanometers. In the exemplary embodiment, diffusion barrier layer 16 is generally continuous and completely covers all of object wall surface 13 that would otherwise contact the hydrocarbon fluid. Diffusion barrier layer 16 may be deposited, or applied, on object wall surface 13 using any suitable process, method, structure, and means.

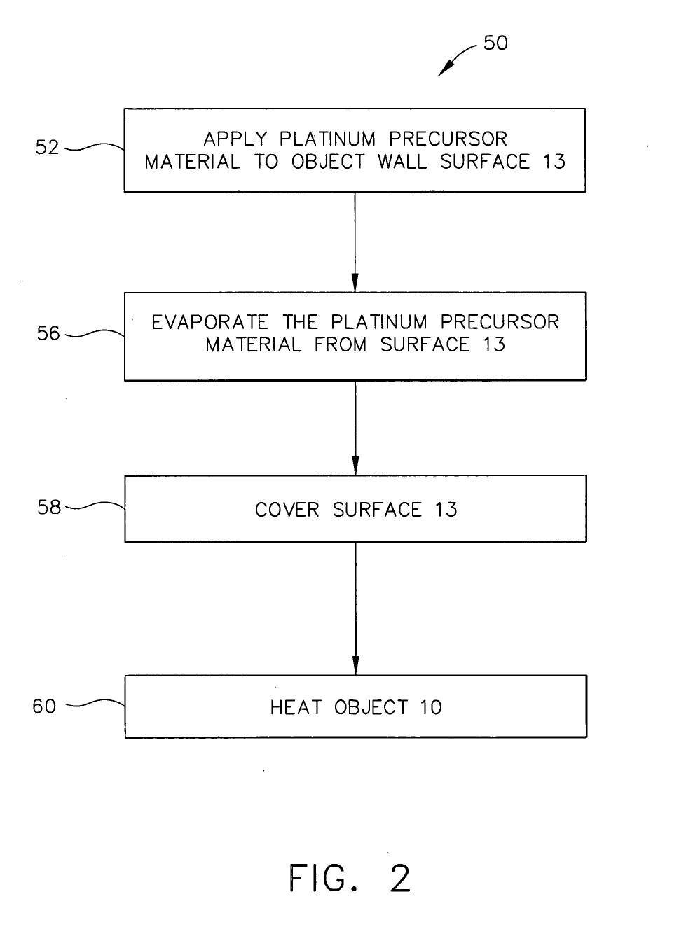

FIG. 2 is a flowchart illustrating an exemplary embodiment of a method 50 for at least partially coating object wall surface 13 (shown in FIG. 1) with coating system 14 (shown in FIG. 1). Method 50 includes applying 52 a platinum precursor material to object wall surface 13, and more specifically in the exemplary embodiment wherein coating system 14 includes diffusion barrier layer 16, applying 52 the platinum precursor material to a surface 54 of diffusion barrier layer 16. Although other platinum precursor materials may be used, in some embodiments, and for example, the platinum precursor material includes any soluble platinum organometallic, such as, but not limited to, platinum pentanedionate. In some embodiments, the platinum precursor material is mixed with another substance, such as, but not limited to a solvent, such as, but not limited to, water, alcohols, MEK, ketones, esters, ethers, and/or liquid hydrocarbons, and the mixture is applied 52 to surface 13. The platinum precursor material or mixture containing the platinum precursor material may be applied 52 to object 10 in any suitable fashion, method, process, and using any suitable structure and means. For example, and although other methods may be used, in some embodiments the platinum precursor material or mixture containing the platinum precursor material is be applied 52 to object surface 13 by spraying, pouring (e.g., using a dropper and/or a beaker, neither of which are shown), and/or dipping object wall surface 13 in the platinum precursor material or a mixture containing the platinum precursor material.

Method 50 also includes evaporating 56 the platinum precursor material and/or the mixture containing the platinum precursor material from object wall surface 13 such that a residue including platinum remains on surface 13. The platinum precursor material and/or the mixture containing the platinum precursor material may be evaporated 56 at any suitable temperature, pressure, and in any suitable medium. For example, and although the platinum precursor material and/or the mixture containing the platinum precursor material may be evaporated 56 at other temperatures, pressures, and in other mediums, in some embodiments evaporation 56 is performed in air at a temperature between about 18° C. and about 26° C. and at about atmospheric pressure. For example, in some embodiments evaporation 56 is performed at a temperature between about 21° C. and about 23° C. After partial or complete evaporation 56, object wall surface 13 is at least partially covered 58 with a covering (not shown), such as, but not limited to, a metallic covering, such as but not limited to, aluminum, steel, nickel, and/or cobalt-based sheet materials.

Method 50 includes heating 60 the at least partially covered object 10 such that the residue evaporates and re-deposits on object wall surface 13 as platinum layer 18 (shown in FIG. 1). Object 10 may be heated 60 to any suitable temperature, pressure, for any suitable amount of time, and using any suitable structure and means. For example, and although object 10 may be heated at other temperatures, pressures, and for other amounts of time, in some embodiments heating 60 is performed at a temperature greater than about 200° C., at about atmospheric pressure, and for at least about 30 minutes. For example, in some embodiments heating 60 is performed at a temperature greater than about 295° C. Moreover, and for example, in some embodiments heating 60 is performed for at least about an hour.

Some of the residue may be deposited on the covering as platinum, and/or some of the platinum precursor material may be lost during evaporation 56 and/or heating 60. For example, in some embodiments greater than about 20% of the platinum precursor material applied 52 to surface 13 is deposited on object wall surface 13 as platinum. For example, in some embodiments greater than about 80% of the platinum precursor material applied 52 to surface 13 is deposited on object wall surface 13 as platinum, and in other embodiments greater than about 90% of the platinum precursor material applied 52 to surface 13 is deposited on object wall surface 13 as platinum. Accordingly, method 50 may facilitate improving a deposition efficiency of the coating of platinum layer 18 on object 10 as compared with at least some other known methods of coating object 10 with platinum layer 18. Moreover, because method 50 may not require equipment such as, but not limited to, chemical vapor deposition (CVD) reactors, method 50 may facilitate reducing an overall cost of coating object 10 with platinum layer 18 by facilitating reducing or eliminating the associated costs of acquiring, leasing, operating, and/or maintaining such equipment. Furthermore, method 50 may facilitate reducing a time of coating object 10 with platinum layer 18 by facilitating reducing the associated time of loading and unloading object 10 into such equipment. As such, method 50 may facilitate more cost-effective coating of a fewer number of objects 10 simultaneously as compared with at least some known methods. Even further, method 50 may facilitate coating of only one or a select number of surfaces of object 12, because such surfaces are coated by the application 52 step(s) described and/or illustrated herein rather than using known chemical vapor deposition, and method 50 may therefore facilitate reducing a time and/or cost of coating object 10 with layer 18.

Exemplary embodiments of methods are described and/or illustrated herein in detail. The methods are not limited to the specific embodiments described herein, but rather, steps of each method may be utilized independently and separately from other steps described herein. Each method step can also be used in combination with other method steps.

When introducing elements/components/etc. of the methods described and/or illustrated herein, the articles “a”, “an”, “the” and “said” are intended to mean that there are one or more of the element(s)/component(s)/etc. The terms “comprising”, “including” and “having” are intended to be inclusive and mean that there may be additional element(s)/component(s)/etc. other than the listed element(s)/component(s)/etc.

While the invention has been described in terms of various specific embodiments, those skilled in the art will recognize that the invention can be practiced with modification within the spirit and scope of the claims.

What is claimed is:

1. A method for at least partially coating a surface of an object with a layer of platinum, said method comprising:
applying a platinum precursor material to the object surface;
evaporating the platinum precursor material from the object surface such that a residue comprising platinum remains on the surface; and
heating the object such that the residue evaporates and re-deposits on the object surface as a layer comprising platinum.

2. A method in accordance with claim 1 wherein applying a platinum precursor material further comprises applying a platinum organometallic to the object surface.

3. A method in accordance with claim 2 wherein applying a platinum organometallic to the object surface comprises applying a platinum pentanedionate to the object surface.

4. A method in accordance with claim 1 wherein applying a platinum precursor material further comprises dissolving the platinum precursor material in a solvent and applying the mixture of solvent and platinum precursor material to the surface, and wherein evaporating the platinum precursor material from the object surface further comprises evaporating the mixture of solvent and platinum precursor material such that a residue comprising platinum remains on the surface.

5. A method in accordance with claim 4 wherein dissolving the platinum precursor material in a solvent further comprises dissolving the platinum precursor material in at least one of water, an alcohol, MEK, a ketone, an ester, an ether, and a liquid hydrocarbon.

6. A method in accordance with claim 1 wherein applying a platinum precursor material further comprises at least one spraying the platinum precursor material on the object surface, pouring the platinum precursor material on the object surface, and dipping the object surface in the platinum precursor material.

7. A method in accordance with claim 1 wherein evaporating the platinum precursor material further comprises evaporating the platinum precursor material in air at a temperature between about 18° C. and about 26° C.

8. A method in accordance with claim 7 wherein evaporating the platinum precursor material further comprises evaporating the platinum precursor material at a temperature between about 21° C. and about 23° C.

9. A method in accordance with claim 1 further comprising covering at least a portion of the object surface with a covering after evaporating the platinum precursor material from the object surface, wherein heating the object comprises heating the at least partially covered object.

10. A method in accordance with claim 9 wherein covering at least a portion of the object surface comprises covering at least a portion of the object surface with at least one of aluminum, steel, nickel, and cobalt.

11. A method in accordance with claim 1 wherein heating the object further comprises heating the object at a temperature greater than about 200° C.

12. A method in accordance with claim 11 wherein heating the object further comprises heating the object at a temperature greater than about 295° C.

13. A method in accordance with claim 1 wherein heating the object further comprises heating the object at about atmospheric pressure.

14. A method in accordance with claim 1 wherein heating the object further comprises heating the object for at least about 30 minutes.

15. A method in accordance with claim 1 wherein applying a platinum precursor material, evaporating the platinum precursor material, and heating the object further comprises applying the platinum precursor material, evaporating the platinum precursor material, and heating the object such that the layer comprising platinum comprises a thickness of between about 50 and about 500 nanometers.

16. A method in accordance with claim 15 wherein applying a platinum precursor material, evaporating the platinum precursor material, and heating the object further comprises applying the platinum precursor material, evaporating the platinum precursor material, and heating the object such that the layer comprising platinum comprises a thickness of between about 200 and about 350 nanometers.

17. A method in accordance with claim 1 wherein applying a platinum precursor material to the object surface, evaporating the platinum precursor material from the object surface, and heating the object further comprises applying the platinum precursor material to a gas turbine engine component, evaporating the platinum precursor material from the gas turbine engine component, and heating the gas turbine engine component.

18. A method in accordance with claim 1 wherein applying a platinum precursor material, evaporating the platinum precursor material, and heating the object further comprises applying the platinum precursor material, evaporating the platinum precursor material, and heating the object such that the layer comprising platinum comprises greater than about 20% of the platinum precursor material applied to the object surface.

19. A method in accordance with claim 18 wherein applying a platinum precursor material, evaporating the platinum precursor material, and heating the object further comprises applying the platinum precursor material, evaporating the platinum precursor material, and heating the object such that the layer comprising platinum comprises greater than about 80% of the platinum precursor material applied to the object surface.

20. A method for at least partially coating an object with a layer of platinum, said method comprising:
applying a mixture of a platinum precursor material and a solvent to a surface of the object that will be exposed to a hydrocarbon fuel;
evaporating the mixture of solvent and platinum precursor material from the object surface such that a residue comprising platinum remains on the surface;
covering at least a portion of the object surface with a covering; and
heating the object such that the residue evaporates and re-deposits on the object surface as a layer comprising platinum.
